(19) United States
(12) Patent Application Publication
(10) Pub. No.: US 2009/0244820 A1
(43) Pub. Date: Oct. 1, 2009

(54) Electronic Apparatus

(75) Inventors: Hiroyuki Kusaka, Mitaka-shi (JP); Jun Watanabe, Fussa-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/325,997

(22) Filed: Dec. 1, 2008

(30) Foreign Application Priority Data
Mar. 28, 2008 (JP) 2008-086929

(51) Int. Cl. H05K 5/00

(52) U.S. Cl. 361/679.1; 361/679.27

(57) ABSTRACT

According to one embodiment, an electronic apparatus includes a functional component contained in a first housing and a camera module contained in a second housing. The second housing is swingable with respect to the first housing. The second housing includes an opening part through which a display screen is exposed to the outside. The camera module includes an end portion configured to project beyond the opening part toward the first housing. The functional component is exposed to the outside of the first housing and located in a position configured to be opposed to the end portion of the camera module. The functional component is provided on a level one step lower than an upper surface of the first housing.

### CROSS-REFERENCE TO RELATED APPLICATIONS

This application is based upon and claims the benefit of priority from Japanese Patent Application No. 2008-086929, filed Mar. 28, 2008, the entire contents of which are incorporated herein by reference.

### BACKGROUND

1. Field

One embodiment of the invention relates to an electronic apparatus provided with a camera module.

2. Description of the Related Art

In recent years, many electronic apparatuses, such as portable computers, are provided with a camera module.

A computer provided with a CCD camera is disclosed in Jpn. Pat. Appln. KOKAI Publication No. 2000-20163. This computer is provided with a main body and a display unit that is swingable with respect to the body. An imaging section that includes the CCD camera is provided in the upper end portion of the display unit. The imaging section is swingable to any desired position within a 180-degree range in the same direction as and opposite to the LCD.

A mobile terminal that is provided with a camera section is disclosed in Jpn. PCT, National Publication No. 2004-80039. The mobile terminal includes an upper housing and a lower housing that are slidable with respect to each other. The camera section is disposed on the upper housing so as to be convex toward the lower housing. The lower housing includes a concave portion that can contain a convex portion of the camera section when the mobile terminal is closed.

In recent years, thinning of display devices has been promoted, and display units for mounting the display devices have been made thinner and thinner. However, camera modules are relatively thick. If a display unit is designed to be thin as a whole, therefore, a camera module cannot be confined within a housing of the display unit and projects to the outside of the housing, in some cases.

In mounting a camera module in a display unit that is swingable with respect to the main body of an apparatus, such as a portable computer, the camera module is made to be convex toward the main body. It is necessary, therefore, to provide a concave portion as an escape for the convex camera module in an upper surface, such as a palm rest, of the main body to be opposed to the display unit. However, such a concave portion is liable to form a dead space in the main body, so that the packaging density of the main body cannot be improved with ease.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the invention;

FIG. 2 is an exemplary plan view of the portable computer shown in FIG. 1;

FIG. 3 is an exemplary sectional view of the portable computer shown in FIG. 1;

FIG. 4 is an exemplary sectional view of the portable computer taken along line F4-F4 of FIG. 3;

FIG. 5 is an exemplary plan view of a portable computer according to a second embodiment of the invention;

FIG. 6 is an exemplary plan view of a portable computer according to a third embodiment of the invention;

FIG. 7 is an exemplary plan view of a portable computer according to a fourth embodiment of the invention;

FIG. 8 is an exemplary side view of a portable computer according to a fifth embodiment of the invention;

FIG. 9 is an exemplary sectional view of the portable computer shown in FIG. 8; and

FIG. 10 is an exemplary sectional view of a portable computer according to a sixth embodiment of the invention.

### DETAILED DESCRIPTION

Various embodiments according to the invention will be described hereinafter with reference to the accompanying drawings. In general, according to one embodiment of the invention, an electronic apparatus comprises a first housing comprising an upper wall; a second housing; a hinge section which connects the second housing to the first housing; a functional component contained in the first housing; a display device which is contained in the second housing and comprises a display screen; and a camera module contained in the second housing. The second housing is swingable between a first posture, in which the second housing covers the upper wall of the first housing, and a second posture, in which the second housing is raised with respect to the first housing. The second housing comprises an opening part through which the display screen is exposed to the outside. The camera module comprises an end portion which projects beyond the opening part toward the first housing when the second housing is in the first posture. The upper wall of the first housing comprises an upper surface. The functional component is exposed to the outside of the first housing and located in a position opposite the end portion of the camera module when the second housing is in the first posture. The functional component is provided on a level one step lower than the upper surface.

Embodiments of the present invention applied to portable computers will now be described with reference to the accompanying drawings.

### First Embodiment

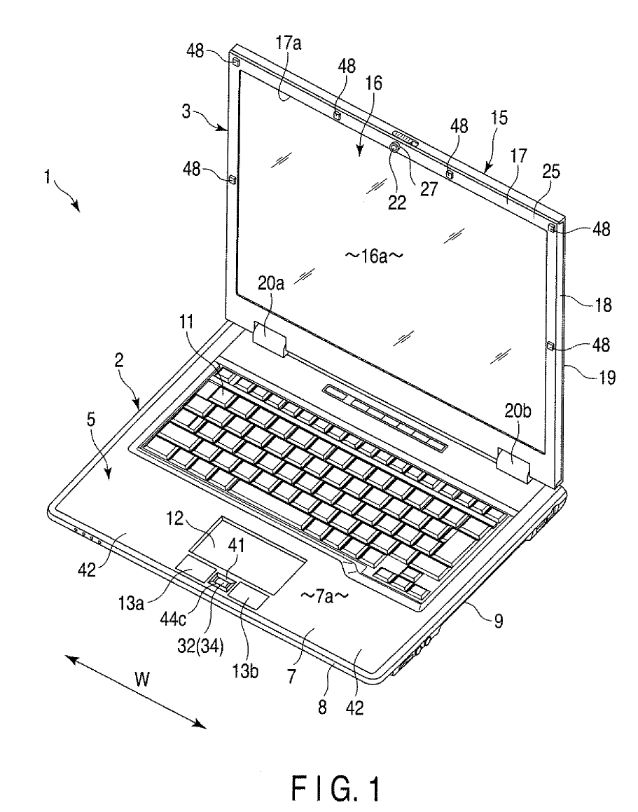

FIGS. 1 to 4 show a portable computer 1 as an electronic apparatus according to a first embodiment of the invention. As shown in FIG. 1, the portable computer 1 comprises a main body (i.e., main unit) 2 and a display unit 3.

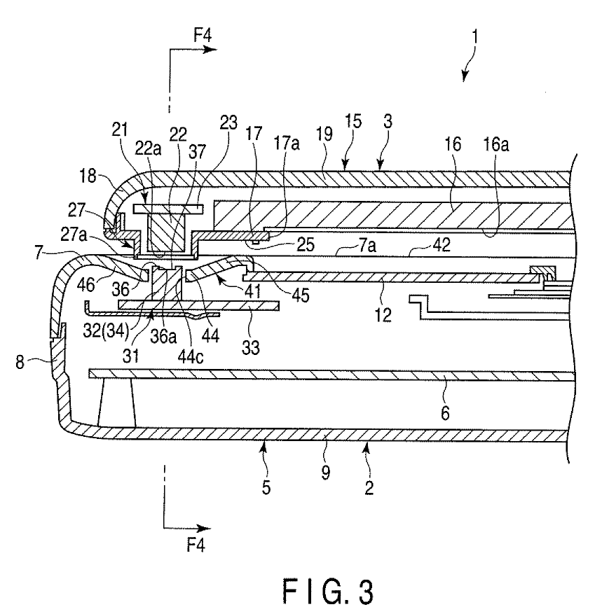

As shown in FIG. 1, the main body 2 is provided with a flat, box-like first housing 5. A circuit board 6 as a mother board and the like are contained in the first housing 5 (see FIG. 3).

As shown in FIGS. 1 and 3, the first housing 5 comprises an upper wall 7, peripheral walls 8, and a lower wall 9. The upper wall 7 spreads substantially horizontally so as to face upward and forms the upper end portion of the first housing 5. As shown in FIG. 1, a keyboard 11, a touchpad 12, and a pair of touchpad buttons 13a and 13b are mounted in the upper wall 7. The peripheral walls 8 extend downward from peripheral edge portions of the upper wall 7, individually. The lower wall 9 extends substantially parallel to the upper wall 7 so as to connect the respective lower edge portions of the peripheral walls 8.

As shown in FIG. 1, the display unit 3 is provided with a flat, box-like second housing 15. A display device 16 is contained in the second housing 15. Specific examples of the display device 16 include a liquid crystal display (LCD), organic electroluminescent (EL) display, etc.

As shown in FIGS. 1 and 3, the second housing 15 comprises a front wall 17, peripheral walls 18, and a rear wall 19. The front wall 17 is opposed to the upper wall 7 of the first housing 5 when the second housing 15 is in a first posture (mentioned later), and is opposed to a user when the second housing 15 is in a second posture (mentioned later). The rear wall 19 is opposed to the display device 16 on the side opposite from the front wall 17. The peripheral walls 18 extend so as to connect the respective peripheral edge portions of the front and rear walls 17 and 19.

The display device 16 comprises a display screen 16a configured to display figures, characters, etc. As shown in FIG. 1, the front wall 17 comprises a relatively wide opening part 17a through which the display screen 16a of the display device 16 is exposed to the outside of the second housing 15. The front wall 17 is an example of “a surface opposed to the first housing”.

As shown in FIG. 1, a pair of hinge sections 20a and 20b, for example, are provided on the rear end portion of the main body 2. The hinge sections 20a and 20b swingably couple the second housing 15 to the first housing 5. Thus, the second housing 15 is swingable between the first posture (i.e., a folded state shown in FIG. 3) in which it is leveled so as to cover the upper wall 7 from above and the second posture (i.e., an open state shown in FIG. 1) in which it is raised with respect to the first housing 5.

As shown in FIG. 3, a camera unit 21 is contained in the second housing 15. The camera unit 21 comprises a camera module 22 (i.e., camera body) and a camera board 23 on which the camera module 22 is mounted. The camera module 22 comprises a case and an optical lens, an imaging device, etc., which are contained in the case.

As shown in FIG. 3, the camera module 22 is situated nearer to the opening part 17a than the camera board 23 is. A distal end portion 22a of the camera module 22 projects forward beyond the opening part 17a of the second housing 15 and a display unit surface 25. Specifically, the distal end portion 22a of the camera module 22 projects beyond the opening part 17a and the display unit surface 25 toward the first housing 5 when the second housing 15 is in the first posture. The display unit surface 25 of the display unit 3 is a surface (i.e., front face) of the front wall 17 that is situated off a projected portion 27, which will be described below.

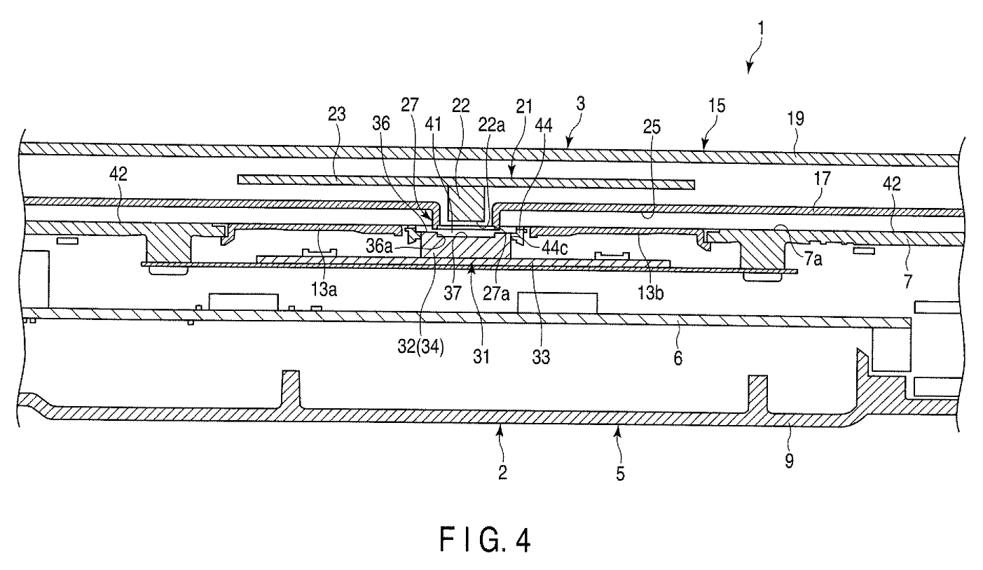

As shown in FIG. 1, the front wall 17 of the second housing 15 is provided with the projected portion 27 in a region where the camera module 22 is contained. As shown in FIGS. 3 and 4, the projected portion 27 is a storage part that contains the camera module 22 without interference.

More specifically, the projected portion 27 is in the form of a cylinder that surrounds the distal end portion 22a of the camera module 22, and is provided with a shooting window part 27a for use as an opening part for the camera in the front. The camera module 22 is exposed to the outside of the second housing 15 through the shooting window part 27a, whereby external shooting can be performed. When the second housing 15 is in the first posture, the projected portion 27 of the front wall 17 projects beyond the display unit surface 25 toward the first housing 5.

As shown in FIGS. 1 and 3, a fingerprint identification unit 31 is contained in the first housing 5. The fingerprint identification unit 31 comprises a fingerprint identification module 32 (i.e., sensor unit) and a fingerprint identification board 33 on which the fingerprint identification module 32 is mounted. The fingerprint identification module 32 is an example of a functional component 34 according to the present invention. The functional component 34 according to the present invention is not limited to a fingerprint identification module but may alternatively be, for example, a touchpad button, power button, speaker, or light emitting diode (LED).

As shown in FIG. 3, the fingerprint identification module 32 comprises a fingerprint identification sensor and a metallic or plastic bezel 36 that covers the sensor. As shown in FIGS. 3 and 4, the bezel 36 is provided in its upper surface with an opening part 36a through which the fingerprint identification sensor is exposed to the outside. The upper surface of the fingerprint identification sensor that is exposed through the opening part 36a serves as a sensor surface 37 (i.e., operating surface) that is configured to read a fingerprint of the user. The fingerprint identification module 32 is provided on a level one step lower than an upper surface 7a of the upper wall 7. The upper surface 7a of the upper wall 7 is a surface in a region (e.g., palm rest 42) that is situated off a recessed portion 41, which will be described below.

As shown in FIGS. 1 and 3, the upper wall 7 of the first housing 5 comprises the recessed portion 41 corresponding to a region in which the fingerprint identification module 32 is provided. The recessed portion 41 according to the present embodiment is a slope for finger rest that guides the user's fingertip toward the sensor surface 37 of the fingerprint identification module 32. The recessed portion 41 is recessed from the upper surface 7a of the upper wall 7 toward the interior of the first housing 5.

As shown in FIG. 3, the recessed portion 41 comprises a bottom surface 44, a first inclined surface 45 formed on the side (rear end side) farther than the bottom surface 44, and a second inclined surface 46 formed on the side (front end side) nearer than the bottom surface 44. In this specification, “far side” and “near side” are defined with respect to the position of the user who faces the display screen 16a.

As shown in FIG. 3, the first inclined surface 45 smoothly connects the far-side end portion (i.e., rear end portion) of the bottom surface 44 to the upper surface 7a of the upper wall 7. The second inclined surface 46 smoothly connects the near-side end portion (i.e., front end portion) of the bottom surface 44 to the upper surface 7a of the upper wall 7. The first and second inclined surfaces 45 and 46 are inclined oppositely with respect to the upper surface 7a of the upper wall 7. The bottom surface 44 of the recessed portion 41 is provided with an opening part 44c through which the fingerprint identification module 32 is exposed to the outside of the first housing 5.

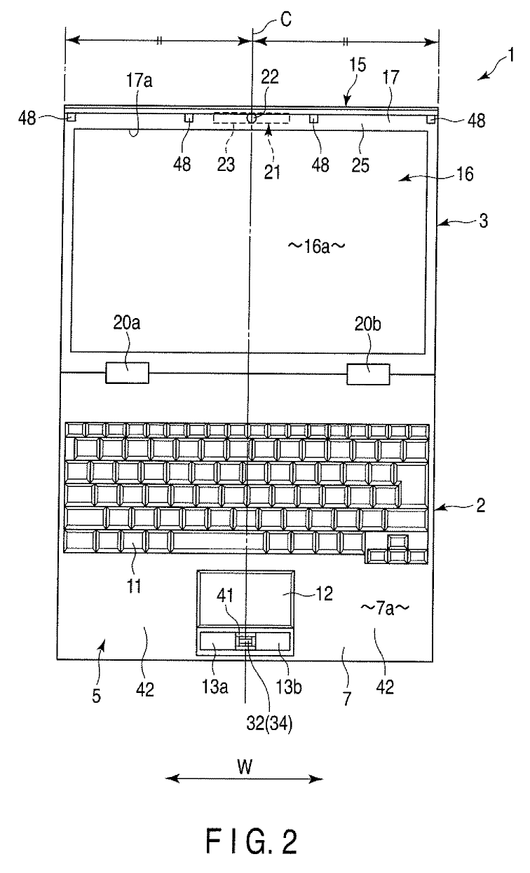

As shown in FIGS. 2, 3 and 4, the fingerprint identification module 32 is located in a position 5 opposite the distal end portion 22a of the camera module 22 when the second housing 15 is in the first posture. Further, the recessed portion 41 is located in a position in the upper wall 7 of the first housing 5 where it is opposite the distal end portion 22a of the camera module 22 when the second housing 15 is in the first posture.

As shown in FIGS. 3 and 4, the recessed portion 41 is recessed lest it interfere with the projected portion 27 of the second housing 15 and the distal end portion 22a of the camera module 22 when the second housing 15 is closed into the first posture. Thus, the recessed portion 41 functions as an escape portion into which the projected portion 27 of the second housing 15 and the distal end portion 22a of the camera module 22 are evacuated.

As shown in FIG. 3, the distal end portion 22a of the camera module 22 according to the present embodiment projects at right angles to the upper wall 7 of the first housing 5 when the second housing 15 is in the first posture. The distal end portion 22a of the camera module 22 is opposed to the bottom surface 44 of the recessed portion 41. As shown in FIG. 3, a clearance that can absorb a component tolerance is defined between the distal end portion 22a of the camera module 22 and the recessed portion 41.

As shown in FIG. 2, the pair of touchpad buttons 13a and 13b according to the present embodiment are provided in an end portion (front end portion) on the user side of the upper wall 7 of the first housing 5. The recessed portion 41 (i.e., the fingerprint identification module 32) is provided between the pair of touchpad buttons 13a and 13b.

The camera module 22 according to the present embodiment is provided in a position for an upper end portion of the second housing 15 when the second housing 15 is in the second posture. The camera module 22 (i.e., the projected portion 27 of the second housing 15) is located on the central part of the second housing 15 with respect to the width W, and is situated on a center line C that passes through the center of the portable computer 1 along the width W.

As shown in FIG. 2, the pair of touchpad buttons 13a and 13b are located based on the central part of the first housing 5 with respect to the width W. In other words, the touchpad buttons 13a and 13b are arranged bilaterally symmetrically with respect to the width of the first housing 5 relative to the center line C. Thus, the recessed portion 41 (i.e., the fingerprint identification module 32) is located in the central part of the first housing 5 with respect to the width W and situated on the center line C.

As shown in FIG. 1, a plurality of interference prevention members 48 are dispersedly provided on the peripheral edge portion of the front wall 17 of the second housing 15. The interference prevention members 48 are, for example, rubber members. When the second housing 15 is in the first posture, the interference prevention members 48 are interposed between the first and second housings 5 and 15 and prevent the second housing 15 from excessively bending toward the first housing 5. The interference prevention members 48 are provided on both sides of the camera module 22 so as to sandwich at least the camera module 22 between them.

The following is a description of the operation of the portable computer 1.

The portable computer 1 is carriable when it is folded so that the second housing 15 is in the first posture. When the portable computer 1 is to be operated, it is opened so that the second housing 15 is in the second posture.

When the second housing 15 is in the second posture, moreover, the camera module 22 thereon is opposed to the user. Still pictures or video images can be taken by using the camera module 22 in this state.

The user can easily move his/her fingertip along the first and second inclined surfaces 45 and 46 of the recessed portion 41 as guides to the sensor surface 37 of the fingerprint identification module 32.

According to the portable computer 1 constructed in this manner, the packaging density of the main body 2 can be improved. Specifically, in the portable computer 1 according to the present embodiment, the fingerprint identification module 32 is located in the position in the first housing 5 where it faces the distal end portion 22a of the camera module 22. The upper wall 7 of the first housing 5 is provided with the recessed portion 41 that is recessed toward the interior of the first housing 5 and comprises the opening part 44c in its bottom surface through which the fingerprint identification module 32 is exposed to the outside. The recessed portion 41 is located in the position where it faces the distal end portion 22a of the camera module 22.

According to the portable computer 1 constructed in this manner, interference of the camera module 22 with the upper wall 7 of the first housing 5 can be avoided without providing another recess than the recessed portion 41 for the fingerprint identification module 32. If the upper wall 7 of the first housing 5 need not be provided with any extra recess as an escape portion, a dead space cannot be easily formed within the apparatus main body 2, so that a high packaging density can be achieved.

If there is a recess separate from the recessed portion 41 for the fingerprint identification module 32, moreover, it entails reductions in size of the touchpad 12 and the buttons. Since the portable computer I according to the present embodiment need not be provided with any recess separate from the recessed portion 41 for the fingerprint identification module 32, the degree of freedom in size of the touchpad 12 and the buttons is increased.

The recessed portion 41 according to the present embodiment is a recess that comprises the bottom surface 44, through which the sensor surface 37 is exposed, and the inclined surfaces 45 and 46 that smoothly connect the bottom surface 44 to the upper surface 7a of the upper wall 7, and serves to guide the user's fingertip toward the sensor surface 37 of the fingerprint identification module 32. The portable computer 1 of the present embodiment absorbs the projection of the camera module 22 by using the recessed portion 41 that is originally provided for a different purpose. By utilizing this recessed portion 41 for the different original purpose, the upper wall 7 of the first housing 5 need not be provided with any recess as an escape portion, so that the main body 2 can enjoy a high packaging density.

The distal end portion 22a of the camera module 22 projects at right angles to the upper wall 7 of the first housing 5 when the second housing 15 is in the first posture. When the distal end portion 22a of the camera module 22 is opposed to the bottom surface 44 of the recessed portion 41, it can be inserted into the innermost part of the recessed portion 41. In other words, the projection of the distal end portion 22a of the camera module 22 can be fully absorbed even by the recessed portion 41 that is relatively shallow. Thus, there is provided the portable computer 1 of which the packaging density of the main body 2 can be improved.

The pair of touchpad buttons 13a and 13b are mounted on the user-side end portion of the upper wall 7 of the first housing 5, and the recessed portion 41 is provided between the touchpad buttons 13a and 13b. Thereupon, the packaging density of the main body 2 can be enhanced for the portable computer 1 in which the camera module 22 is mounted in the position for the upper end portion of the second housing 15.

The camera module 22 is located on the central part of the second housing 15 with respect to the width W, while the recessed portion 41 is located in the central part of the first housing 5 with respect to the width W. Thereupon, the packaging density of the main body 2 can be enhanced for the portable computer 1 in which the pair of touchpad buttons 13a and 13b are located based on the central part of the first housing 5 with respect to the width W.

### Second Embodiment

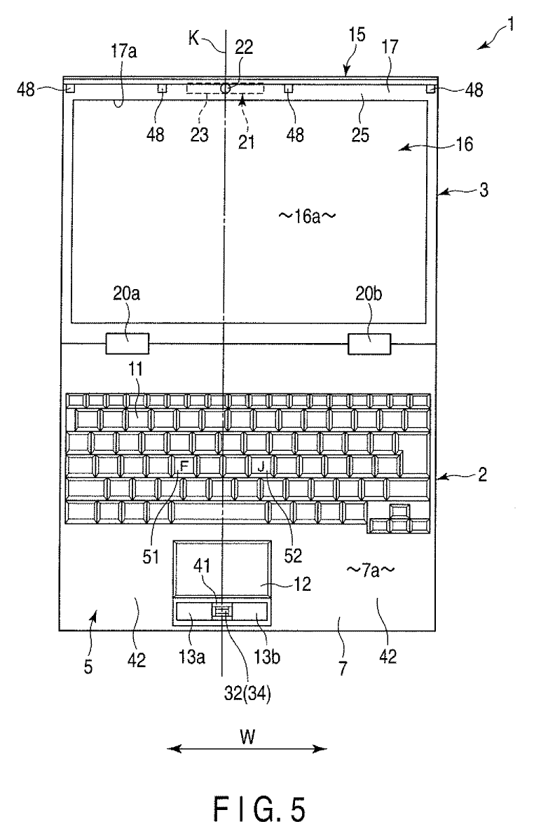

A portable computer 1 as an electronic apparatus according to a second embodiment of the present invention will now be described with reference to FIG. 5. Like numbers are used to designate configurations with like or similar functions to those of the configurations of the first embodiment, and a description of those configurations is omitted.

As shown in FIG. 5, a touchpad 12 and a pair of touchpad buttons 13a and 13b according to the present embodiment are located based on a keyboard home position of a keyboard 11. In other words, the touchpad buttons 13a and 13b are arranged bilaterally symmetrically with respect to the width W of a first housing 5 relative to a keyboard center line K that extends between an F key 51 and a J key 52 for use as reference keys on the keyboard 11. The touchpad 12 and a recessed portion 41 (i.e., a fingerprint identification module 32) are situated on the keyboard center line K and are shifted from the central part of the first housing 5 with respect to the width W.

A camera module 22 (i.e., a projected portion 27 of a second housing 15) is shifted from the central part of the second housing 15 with respect to the width W so as to face the recessed portion 41 between the pair of touchpad buttons 13a and 13b. In other words, the camera module 22 (i.e., the projected portion 27 of the second housing 15) is situated on the keyboard center line K. Other configurations of the portable computer 1 than those described above are the same as those of the first embodiment.

According to the portable computer 1 constructed in this manner, as in the first embodiment, a dead space cannot be easily formed within a mine body 2, so that the packaging density of the main body 2 can be improved.

The recessed portion 41 is shifted from the central part of the second housing 15 with respect to the width W, while the camera module 22 is shifted from the central part of the second housing 15 with respect to the width W so as to face the recessed portion 41 between the pair of touchpad buttons 13a and 13b. Thereupon, the packaging density of the main body 2 can be enhanced for the portable computer 1 in which the pair of touchpad buttons 13a and 13b are located based on the keyboard home position of the keyboard 11.

### Third Embodiment

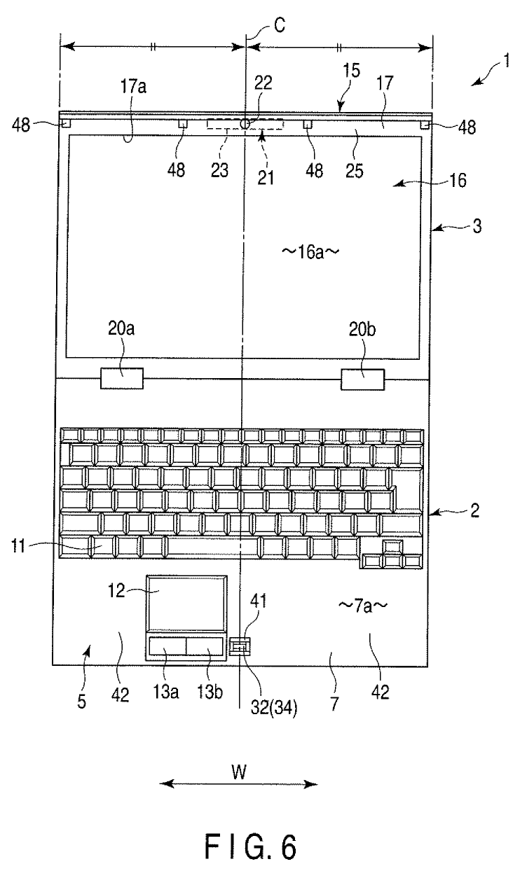

A portable computer 1 as an electronic apparatus according to a third embodiment of the present invention will now be described with reference to FIG. 6. Like numbers are used to designate configurations with like or similar functions to those of the configurations of the first embodiment, and a description of those configurations is omitted.

As shown in FIG. 6, a fingerprint identification module 32 according to the present embodiment is not provided between a pair of touchpad buttons 13a and 13b. A recessed portion 41 (i.e., the fingerprint identification module 32) is located in the central part of a first housing 5 with respect to the width W and situated on a center line C. A camera module 22 (i.e., a projected portion 27 of a second housing 15) is located on the central part of the second housing 15 with respect to the width W and situated on the center line C.

As shown in FIG. 6, a touchpad 12 and the pair of touchpad buttons 13a and 13b are situated off the central part of the first housing 5 with respect to the width and beside the fingerprint identification module 32. Other configurations of the portable computer 1 than those described above are the same as those of the first embodiment.

According to the portable computer 1 constructed in this manner, as in the first embodiment, a dead space cannot be easily formed within a main body 2, so that the packaging density of the main body 2 can be improved.

### Fourth Embodiment

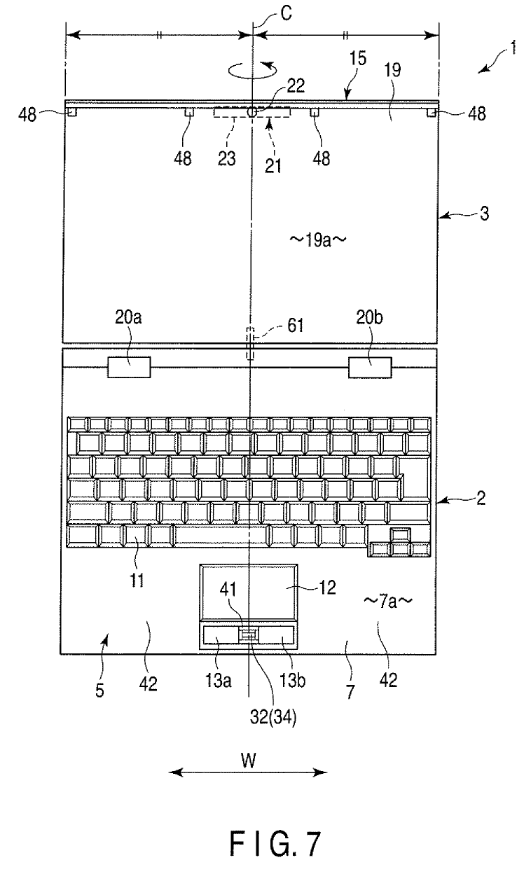

A portable computer 1 as an electronic apparatus according to a fourth embodiment of the present invention will now be described with reference to FIG. 7. Like numbers are used to designate configurations with like or similar functions to those of the configurations of the first embodiment, and a description of those configurations is omitted.

An example of the portable computer 1 according to the present embodiment is a tablet PC with a tablet function. As shown in FIG. 7, the portable computer 1 comprises a second hinge section 61 that supports a display unit 3 for 180-degree reversal, as well as first hinge sections 20a and 20b. Thus, the portable computer 1 is deformable between a first state in which a display screen 16a is leveled so as to face a first housing 5 and a second state in which the display screen 16a is leveled so as to give the back to the first housing 5.

As shown in FIG. 7, a camera module 22 is provided on the side of a rear wall 19 of a second housing 15. The camera module 22 comprises a distal end portion 22a that projects beyond a surface 19a of the rear wall 19 (i.e., a surface that covers a large part of the rear wall 19) toward the first housing 5 when the second housing 15 is in the second state. Another camera module 22 may or may not be provided on the side of a front wall 17. The camera module 22 may be configured to swing to any desired position within a 180-degree range in the same direction as and opposite to the display screen 16a. The camera module 22 (i.e., a projected portion 27 of the second housing 15) is located on the central part of the second housing 15 with respect to the width W and situated on a center line C.

As shown in FIG. 7, a fingerprint identification module 32 is located in a position in the first housing 5 where it faces the distal end portion 22a of the camera module 22 when the second housing 15 is in the first posture. Further, a recessed portion 41 is located in a position in an upper wall 7 of the first housing 5 where it faces the distal end portion 22a of the camera module 22 when the second housing 15 is in the first posture. Thus, the recessed portion 41 (i.e., the fingerprint identification module 32) is located in the central part of the first housing 5 with respect to the width W and situated on the center line C. Other configurations of the portable computer 1 than those described above are the same as those of the first embodiment.

According to the portable computer 1 constructed in this manner, as in the first embodiment, a dead space cannot be easily formed within a main body 2, so that the packaging density of the main body 2 can be improved. According to the portable computer 1 of the present embodiment, moreover, the projection of the camera module 22 can be absorbed by the recessed portion 41 even when the display unit 3 is closed by being reversely rotated for 180 degrees.

### Fifth Embodiment

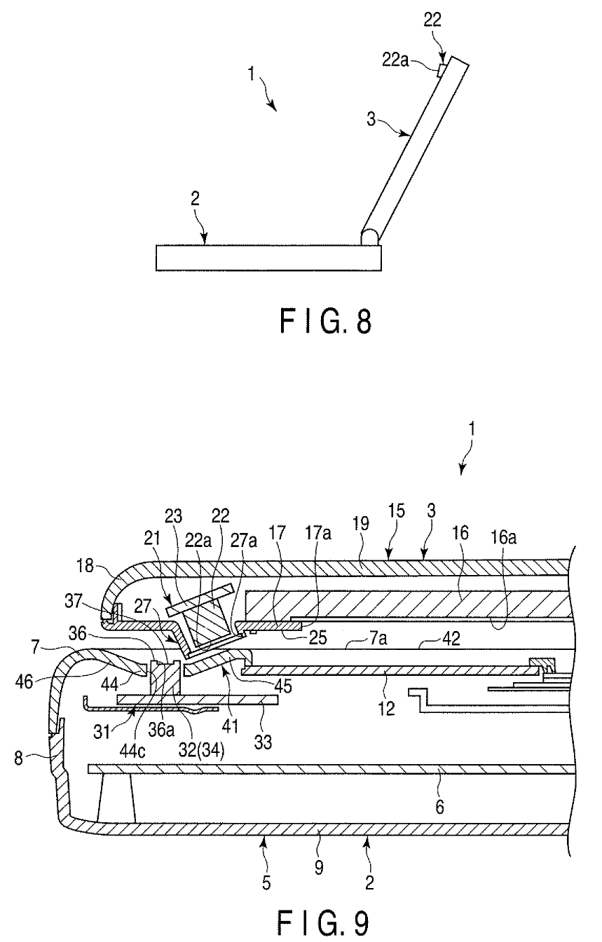

A portable computer 1 as an electronic apparatus according to a fifth embodiment of the present invention will now be described with reference to FIGS. 8 and 9. Like numbers are used to designate configurations with like or similar functions to those of the configurations of the first embodiment, and a description of those configurations is omitted.

FIG. 8 is an exemplary side view schematically showing the portable computer 1 according to the present embodiment. As shown in FIG. 8, a camera module 22 is mounted at an angle to a second housing 15 so that a distal end portion 22a of the camera module 22 projects toward the user when a display unit 3 is opened.

As shown in FIG. 9, the distal end portion 22a of the camera module 22 projects obliquely with respect to an upper wall 7 of a first housing 5. A projected portion 27 of the second housing 15 projects obliquely with respect to the upper wall 7 of the first housing 5 so as to surround the distal end portion 22a of the camera module 22. The distal end portion 22a of the camera module 22 (i.e., the projected portion 27 of the second housing 15) is located opposite a first inclined surface 45 of a recessed portion 41. Other configurations of the portable computer 1 than those described above are the same as those of the first embodiment.

According to the portable computer 1 constructed in this manner, as in the first embodiment, a dead space cannot be easily formed within a main body 2, so that the packaging density of the main body 2 can be improved.

If the distal end portion 22a of the camera module 22 projects toward the user when the display unit 3 is opened, the user feels less discomfort, apparently seeing the camera module 22 directly in front of him/her. If the distal end portion 22a of the camera module 22 (i.e., the projected portion 27 of the second housing 15) is opposed to the first inclined surface 45 of the recessed portion 41, the distal end portion 22a of the camera module 22 that is inclined with respect to the upper wall 7 of the first housing 5 can be fully absorbed even by the recessed portion 41 that is relatively shallow.

### Sixth Embodiment

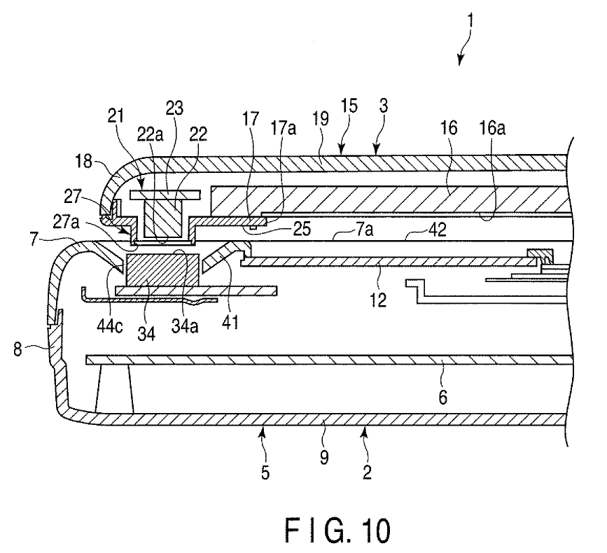

A portable computer 1 as an electronic apparatus according to a sixth embodiment of the present invention will now be described with reference to FIG. 10. Like numbers are used to designate configurations with like or similar functions to those of the configurations of the first embodiment, and a description of those configurations is omitted.

In the portable computer 1 according to the present embodiment, as shown in FIG. 10, a functional component 34 is mounted in place of a fingerprint identification module 32. The functional component 34 may be, for example, a touchpad button, power button, speaker, or LED.

The functional component 34 is exposed to, for example, the front end portion of an upper wall 7 and is provided on a level one step lower than an upper surface 7a of the upper wall 7. Specifically, an operating surface 34a (i.e., functional surface) of the functional component 34 is situated on a level one step lower than the upper surface 7a of the upper wall 7. Thus, the user can be prevented from touching the functional component 34 by mistake if the component 34 is any of various buttons, for example.

As shown in FIG. 10, the functional component 34 is located in a position in a first housing 5 opposite a distal end portion 22a of a camera module 22 when a second housing 15 is in the first posture, and is exposed to the outside of the first housing 5 through an opening part 44c. Other configurations of the portable computer 1 than those described above are the same as those of the first embodiment.

According to the portable computer 1 constructed in this manner, a dead space cannot be easily formed within a main body 2, so that the packaging density of the main body 2 can be improved. Specifically, the functional component 34 is located opposite the distal end portion 22a of the camera module 22 and mounted on a level one step lower than the upper surface 7a of the upper wall 7. Thus, interference of the camera module 22 with the upper wall 7 of the first housing 5 can be avoided without providing an additional recess. If the upper wall 7 of the first housing 5 need not be provided with any extra recess as an escape portion, a dead space cannot be easily formed within the main body 2, so that a high packaging density can be achieved.

Although the portable computers 1 according to the first to sixth embodiments of the present invention have been described herein, the invention is not limited to those embodiments. The components according to the first to sixth embodiments may be suitably combined in use. For example, the layouts of the second and third embodiments may be used for the fourth or fifth embodiment.

The present invention is not limited directly to the embodiments described above, and its components may be embodied in modified forms without departing from the scope or spirit of the invention. For example, the camera module 22 may be provided on the lower end portion of the second housing 15. In this case, the functional component 34, fingerprint identification module 32, recessed portion 41, etc., are provided on the rear end portion (inner end portion) of the first housing 5. The recessed portion 41 may formed independently of a large part of the upper wail 7 and mounted as a part of the upper wall 7.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a first housing comprising an upper wall;
a second housing;
a hinge section which connects the second housing to the first housing;
a fingerprint identification module contained in the first housing;
a display device which is contained in the second housing and comprises a display screen; and
a camera module contained in the second housing,
the second housing being swingable between a first posture, in which the second housing covers the upper wall of the first housing, and a second posture, in which the second housing is raised with respect to the first housing, and the second housing comprising an opening part through which the display screen is exposed to the outside,
the camera module comprising an end portion which projects beyond the opening part toward the first housing when the second housing is in the first posture,
the upper wall of the first housing comprising a recessed portion which is recessed toward the interior of the first housing and is provided with an opening part through which the fingerprint identification module is exposed to the outside, the recessed portion being located in a position opposite the end portion of the camera module when the second housing is in the first posture.

2. An electronic apparatus of claim 1, wherein the upper wall of the first housing comprises an upper surface situated off the recessed portion, and the recessed portion comprises a bottom surface provided with the opening part through which the fingerprint identification module is exposed and an inclined surface which connects the bottom surface to the upper surface.

3. An electronic apparatus of claim 2, wherein the end portion of the camera module projects at right angles to the upper wall of the first housing and faces a bottom surface of the recessed portion when the second housing is in the first posture.

4. An electronic apparatus of claim 1, further comprising a pair of touchpad buttons provided in the upper wall of the first housing, and
wherein the recessed portion is provided between the pair of touchpad buttons.

5. An electronic apparatus of claim 4, wherein the camera module is located on a widthwise central part of the second housing, and the recessed portion is located in the widthwise central part of the first housing such that the pair of touchpad buttons are located based on a widthwise central part of the first housing.

6. An electronic apparatus of claim 4, further comprising a keyboard provided on the upper wall of the first housing, and
wherein the recessed portion is shifted from a widthwise central part of the first housing such that the pair of touchpad buttons are located based on a keyboard home position of the keyboard, and the camera module is shifted from a widthwise central part of the second housing.

7. An electronic apparatus comprising:
a first housing comprising an upper wall;
a second housing;
a hinge section which connects the second housing to the first housing;
a functional component contained in the first housing;
a display device which is contained in the second housing and comprises a display screen; and
a camera module contained in the second housing,
the second housing being swingable between a first posture, in which the second housing covers the upper wall of the first housing, and a second posture, in which the second housing is raised with respect to the first housing, and the second housing comprising an opening part through which the display screen is exposed to the outside,
the camera module comprising an end portion which projects beyond the opening part toward the first housing when the second housing is in the first posture,
the upper wall of the first housing comprising an upper surface,
the functional component being exposed to the outside of the first housing and located in a position opposite the end portion of the camera module when the second housing is in the first posture, the functional component being provided on a level one step lower than the upper surface.
